(19) United States
(12) Patent Application Publication
(10) Pub. No.: US 2025/0290834 A1
(43) Pub. Date: Sep. 18, 2025

(54) PREPARATION OF PLANAR LAMELLA FROM A MULTI-LAYER STRUCTURE

(71) Applicant: FEI Company, Hillsboro, OR (US)

(72) Inventors: Petra Binknerová, Brno (CZ); Jaroslav Stárek, Brno (CZ); Zoltán Orémuš, Brno (CZ); Hana Šandová, Brno (CZ); Michal Barborík, Brno (CZ); Pavel Goš, Brno (CZ)

(21) Appl. No.: 18/606,909

(22) Filed: Mar. 15, 2024

(51) Int. Cl. G01N 1/28

(52) U.S. Cl. CPC G01N 1/286

(57) ABSTRACT

A method for preparing a planar lamella from a multi-layer structure includes milling a first marker in a first side surface of the multi-layer structure, the multi-layer structure including multiple layers that are parallel to a top surface of the multi-layer structure, obtaining a first image of the first side surface, the first image showing the first marker, determining, based on the first image, a pattern offset, and milling, based on the pattern offset, a target marker on a target layer of the multiple layers. One or more non-transitory computer-readable storage media storing instructions that, upon execution on a system, cause the system to perform operations of the method.

The present disclosure is directed to charged particle microscopy. More particularly, the present disclosure describes methods and systems in process pattern placement alignment for precises thinning marks placement.

### BACKGROUND OF THE INVENTION

Charged particle microscopy can be used to investigate and analyze samples, for example using transmission electron microscopes (TEM). To view samples with a TEM, thin lamellae are formed from the sample including various structures and other features to be imaged with the TEM. Lamellae are thin membranes that are partially transparent to electrons and are typically between 7 nm to 25 nm in thickness. Due to the small dimensions of the lamellae, careful preparation of the lamellae is required to preserve structures in the sample for imaging.

### SUMMARY OF THE INVENTION

According to one embodiment, a method for preparing a planar lamella from a multi-layer structure includes milling a first marker in a first side surface of the multi-layer structure, the multi-layer structure including multiple layers that are parallel to a top surface of the multi-layer structure, obtaining a first image of the first side surface, the first image showing the first marker, determining, based on the first image, a pattern offset, and milling, based on the pattern offset, a target marker on a target layer of the multiple layers.

The method may include various optional embodiments. The method may include thinning, based on the first marker, the multi-layer structure such that the target layer is included in the planar lamella and one or more other layers of the multiple layers are excluded from the planar lamella. The method may include milling, based on the first image, a second marker in the first side surface and obtaining a second image of the first side surface, the second image showing the first marker and the second marker, where the pattern offset is further determined based on the second image. The method may include determining, based on the first image, a first position of the first marker, milling, based on the first position, a second marker in the first side surface such that the second marker is milled at an expected position relative to the first position, and obtaining a second image of the first side surface, the second image showing the second marker. The method may include determining, based on the second image, a second position of the second marker where the pattern offset is determined based on a difference between the expected position and the second position. The first marker may be a first line milled based on a determination of a fiducial on the first side surface and the second marker may be a second line milled based on the first marker. The first side surface may include a first portion and a second portion where the first image shows that the first portion includes the first marker and that the second portion includes the multiple layers. The target marker may be milled in the second portion. The method may include preparing the multi-layer structure to have a particular size, the multi-layer structure prepared from a sample by at least removing a first portion of the sample, wherein the first portion is removed to define the first side surface. The multi-layer structure may be further prepared from the sample by at least removing a second portion of the sample where the second portion is removed to define a second side surface opposite the first side surface and where the particular size is a distance between the first side surface and the second side surface. The first portion and the second portion may be removed by at least polishing a third side surface of the sample where the third side surface intersects the first side surface and the second side surface and is polished at a non-zero angle relative to the top surface. The method may include obtaining a second image of the third side surface and cutting the first portion and the second portion based on the second image. The first portion and the second portion may be removed by at least obtaining a second image of a third side surface of the sample where the third side surface intersects the first side surface and the second side surface, determining, based on the second image, a set of features of the sample in the third side surface where the second image shows the set of features, determining, based on the second image, edges of the third side surface, determining a parameter indicating the particular size, and cutting the first portion and the second portion based on the set of features, the edges, and the parameter. The first portion and the second portion may be removed by at least obtaining a second image of a third side surface of the sample where the third side surface intersects the first side surface and the second side surface, determining a region of interest within the third side surface, depositing a material in the region of interest, and cutting the first portion and the second portion based on analysis of images showing the third side surface and based on image edge detection of the region of interest. The region of interest may be determined by at least, based on the second image, determining a first position of a protective layer on the top surface, a second position of a target in the third side surface, a set of features of the third side surface, and edges of the third side surface. The method may include defining the region of interest to include the target, be positioned at the second position away from the first position, include a portion of the set of features, and have the edges. The first portion may be removed by at least obtaining images of a third side surface of the sample where the third side surface intersects the first side surface and the second side surface and removing, via ion beams and the images, slices of the first portion where the slices are parallel to the first side surface.

According to another embodiment, one or more non-transitory computer-readable storage media storing instructions that, upon execution on a system, cause the system to perform operations including milling a first marker in a first side surface of the multi-layer structure, the multi-layer structure including multiple layers that are parallel to a top surface of the multi-layer structure, obtaining a first image of the first side surface, the first image showing the first marker, determining, based on the first image, a pattern offset, milling, based on the pattern offset, a target marker on a target layer of the multiple layers, and thinning, based on the first marker, the multi-layer structure such that the target layer is included in the planar lamella and one or more other layers of the multiple layers are excluded from the planar lamella.

The one or more non-transitory computer-readable storage media may include various optional embodiments. The operations may further include milling, based on the first image, a second marker in the first side surface and obtaining a second image of the first side surface, the second image showing the first marker and the second marker where the pattern offset is further determined based on the second image. The operations may further include determining, based on the first image, a first position of the first marker, milling, based on the first position, a second marker in the first side surface such that the second marker is milled at an expected position relative to the first position, and obtaining a second image of the first side surface, the second image showing the second marker. The operations may further include determining, based on the second image, a second position of the second marker where the pattern offset is determined based on a difference between the expected position and the second position. The operations may further include preparing the multi-layer structure to have a particular size, the multi-layer structure prepared from a sample by at least removing a first portion of the sample, wherein the first portion is removed to define the first side surface. The multi-layer structure may be further prepared from the sample by at least removing a second portion of the sample where the second portion is removed to define a second side surface opposite the first side surface and where the particular size is a distance between the first side surface and the second side surface. The first portion and the second portion may be removed by at least obtaining a second image of a third side surface of the sample where the third side surface intersects the first side surface and the second side surface, determining a region of interest within the third side surface, depositing a material in the region of interest, and cutting the first portion and the second portion based on analysis of images showing the third side surface and based on image edge detection of the region of interest.

### BRIEF DESCRIPTION OF THE DRAWINGS

The foregoing aspects and many of the attendant advantages of the present disclosure will become more readily appreciated as the same become better understood by reference to the following detailed description, when taken in conjunction with the accompanying drawings.

FIG. 1 is a schematic diagram of an example dual beam system for preparing samples using segmented endpointing, according to some embodiments.

FIG. 2 is a multi-layer structure, according to some embodiments.

FIG. 3 is a planar lamella formed from a multi-layer structure, according to some embodiments.

FIG. 4 is a schematic of processing a planar lamella from a multi-layer structure, according to some embodiments.

FIG. 5 is a multi-layer structure showing spatial relationships for processing a planar lamella, according to some embodiments.

FIG. 6A illustrates a top view of a multi-layer structure, according to some embodiments.

FIG. 6B illustrates a side view of the multi-layer structure of FIG. 6A, according to some embodiments.

FIG. 7 illustrates processing of a sample to form multi-layer structure of a particular size, according to some embodiments.

FIG. 8 illustrates a sidecut of a multi-layer structure to form a sample, according to some embodiments.

FIG. 9 illustrates processing of a multi-layer structure to form a sample, according to some embodiments.

FIG. 10 illustrates a method of detecting a feature, according to some embodiments.

FIG. 11 illustrates a region of interest of a multi-layer structure, according to some embodiments.

FIG. 12 illustrates deposition of a material proximate to a region of interest of a multi-layer structure, according to some embodiments.

FIGS. 13A-13D illustrate a process for preparing a planar lamella from a multi-layer structure, according to some embodiments.

FIG. 14 is a flowchart of a method, according to some embodiments.

FIG. 15 is a flowchart of a method, according to some embodiments.

In the drawings, like reference numerals refer to like parts throughout the various views unless otherwise specified. Not all instances of an element are necessarily labeled to reduce clutter in the drawings where appropriate. The drawings are not necessarily to scale, emphasis instead being placed upon illustrating the principles being described.

### DETAILED DESCRIPTION OF THE INVENTION

While exemplary embodiments have been illustrated and described, it will be appreciated that various changes can be made therein without departing from the spirit and scope of the disclosure.

Charged particle microscopy is used in various industries, including the semiconductor industry, to analyze micrometer and nanometer scale structures. For example, semiconductor devices can include nanometer scale transistors densely arranged within a silicon wafer. Images obtained with charged particle microscopy can be used to improve process control, evaluate the quality of fabricated devices, and improve yields. In the case of semiconductor devices, objects like field effect transistors (FETs) may be formed within the larger silicon wafer and adjacent to several other structures, including other FETs, vias, diode junctions, and the like. Because of the extremely small scale and dense packing of the elements, imaging of these elements can be improved by careful preparation of the sample.

Imaging samples with a charged particle microscope can include using a transmission electron microscope (TEM), a scanning electron microscope (SEM), a scanning TEM (STEM), or related techniques. To image samples using these techniques, a lamella is formed and removed from the larger substrate (e.g., the silicon wafer). The lamella can include the structures forming the devices (e.g., FETs). The lamella can be formed and removed using a dual beam charged particle microscope system, which typically includes a focused ion beam (FIB) and a SEM. During the lamella formation process, the FIB is used to remove material from the substrate, leaving the lamella as a portion of the remaining material, while the SEM is used for imaging to guide the FIB process. This process has become conventional in many industries, not just the semiconductor industry, and is used to image and analyze almost any type of micron or nanometer scale structure buried within a surrounding substrate.

Once a lamella has been removed from the surrounding material, additional milling with the FIB can be performed to further thin the lamella. For example, an initial lamella sample from a substrate can be formed with a thickness on the order of 1 μm. Milling the lamella in one or more steps with various ion beam energies (e.g., 30 kV, 2 kV) can reduce a portion of the initial lamella sample to thicknesses of less than 100 nm, including, for example, lamellae having thicknesses of 50 nm, 20 nm, 15 nm, and less than 10 nm. By thinning the lamella, image resolution of structures within the lamella can be improved.

In the case of semiconductor devices, the continued development of smaller scale structures that are more closely packed within their substrate has led to challenges in forming suitable lamellas for imaging purposes. Small scale structures may be arranged in several layers within the same substrate, such that structures of layers in front of or behind the structure of interest can obscure or occlude the structure of interest during imaging. For example, a lamella can include a line of transistor elements (e.g., semiconductor channel fins) spaced apart from another line of transistor elements by a certain distance (e.g., 50 nm in one particular example). To image only one line of transistor elements, the lamella can be thinned to remove the material containing the other line of transistor elements.

In many cases, the structures of interest may be at or near the surface of the lamella. For example, a structure may have multiple layers and there may be a subset of layers (e.g., one or more layers) of interest. Thus, milling the lamella to a suitable thickness can include removing material from the lamella until the structures of interest are at or near the surface of the lamella, as determined by imaging the surface of the lamella. Because the milling process can remove material from the structures of interest, careful control of the end point of the FIB milling is desired. This control is typically achieved by imaging the surface of the sample during milling to identify structures of interest. As used herein, the term “endpoint” or “endpointer” can refer to the features or shape that characterizes the desired surface of the lamella, while the term “endpointing” can refer to the technique of controlling the milling of a sample based on one or more endpoints. Thus, milling of the lamella with the FIB can be stopped when the surface, or a portion thereof, matches an endpoint as determined by image analysis. Specific details about using a single endpoint to determine the depth of milling of a sample may be found in U.S. Patent Application Publication No. 2023/0307209, the contents of which are incorporated herein by reference in their entirety for all purposes.

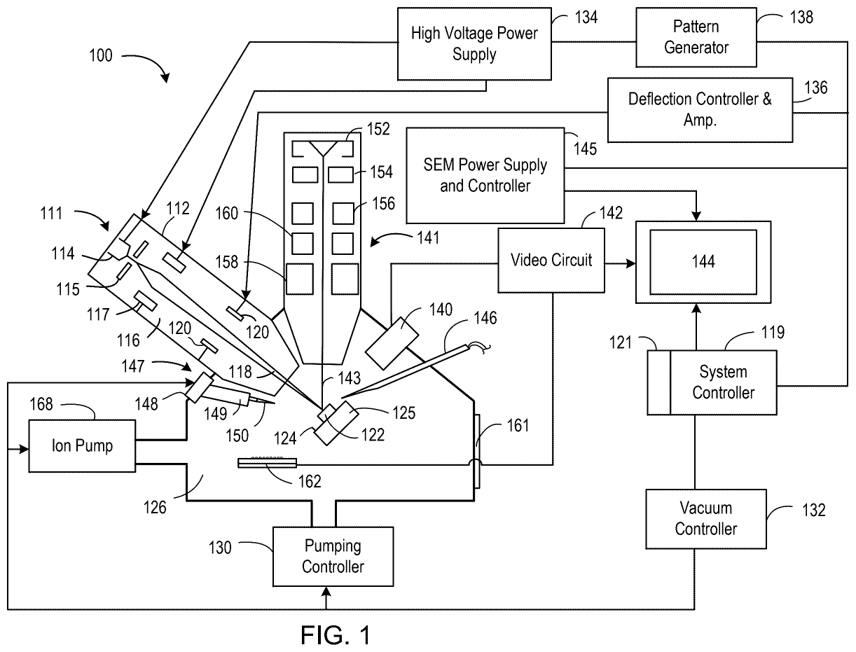

FIG. 1 is a schematic diagram of an example dual beam system 100, according to some embodiments. System 100 may be used to implement the techniques discussed herein. In some embodiments, the system 100 will perform sample milling and endpoint detection, including segmented endpoint detection. However, in other embodiments, the milling algorithms may be performed by a computing system coupled to system 100, such as at a user's desk or a cloud based computing system. In either embodiment, the determination of milling endpoint may be provided to system 100 for automatic milling control to ensure that the surface of the thinned lamella is correctly obtained. While an example of suitable hardware is provided below, the invention is not limited to being implemented in any particular type of hardware.

An SEM 141, along with power supply and control unit 145, is provided with the dual beam system 100. An electron beam 143 is emitted from a cathode 152 by applying voltage between cathode 152 and an anode 154. Electron beam 143 is focused to a fine spot by means of a condensing lens 156 and an objective lens 158. Electron beam 143 is scanned two-dimensionally on the specimen by means of a deflector 160. Operation of condensing lens 156, objective lens 158, and deflector 160 is controlled by power supply and control unit 145.

Electron beam 143 can be focused onto substrate 122, which is on stage 125 within lower chamber 126. Substrate 122 may be located on a surface of stage 125 or on TEM sample holder 124, which extends from the surface of stage 125.

When the electrons in the electron beam strike substrate 122, secondary electrons are emitted. These secondary electrons are detected by secondary electron detector 140. In some embodiments, STEM detector 162, located beneath the TEM sample holder 124 and the stage 125 collects electrons that are transmitted through the sample mounted on the TEM sample holder.

System 100 also includes FIB system 111 which comprises an evacuated chamber having an ion column 112 within which are located an ion source 114 and focusing components 116 including extractor electrodes and an electrostatic optical system. The axis of focusing column 116 may be tilted, 52 degrees for example, from the axis of the electron column 141. The ion column 112 includes an ion source 114, an extraction electrode 115, a focusing element 117, deflection elements 120, which operate in concert to form focused ion beam 118. Focused ion beam 118 passes from ion source 114 through focusing components 116 and between electrostatic deflection means schematically indicated at 120 toward substrate 122, which may comprise, for example, a semiconductor wafer positioned on movable stage 125 within lower chamber 126. In some embodiments, a sample may be located on TEM grid holder 124, where the sample may be a chunk extracted from substrate 122. The chunk may then undergo further processing with the FIB to form a final lamella of a desired thickness in accordance with techniques disclosed herein.

Stage 125 can move in a horizontal plane (X and Y axes) and vertically (Z axis). Stage 125 can also tilt and rotate about the Z axis. In some embodiments, a separate TEM sample stage 124 can be used. Such a TEM sample stage will also preferably be moveable in the X, Y, and Z axes as well as tiltable and rotatable. In some embodiments, the tilting of the stage 125/TEM holder 124 may be in and out of the plane of the ion beam 118, and the rotating of the stage is around the ion beam 118. As used herein to illustrate the disclosed techniques, such relationship will be maintained when discussing rotation and tilting of a sample. Of course, the opposite definitions could be used but would still fall within the contours of the present disclosure.

A door 161 is opened for inserting substrate 122 onto stage 125. Depending on the tilt of the stage 124/125, the Z axis will be in the direction of the optical axis of the relevant column. For example, during a data gathering stage of the disclosed techniques, the Z axis will be in the direction, e.g., parallel with, the FIB optical axis as indicated by the ion beam 118. In such a coordinate system, the X and Y axis will be referenced from the Z-axis. For example, the X-axis may be in and out of the page showing FIG. 1, whereas the Y-axis will be in the page, all while all three axes maintain their perpendicular nature to one another.

An ion pump 168 is employed for evacuating neck portion. The chamber 126 is evacuated with turbomolecular and mechanical pumping system 130 under the control of vacuum controller 132. The vacuum system provides within chamber 126 a vacuum of between approximately 1×10⁻⁷ Torr and 5×10⁻⁴ Torr. If an etch assisting, an etch retarding gas, or a deposition precursor gas is used, the chamber background pressure may rise, typically to about 1×10⁻⁵ Torr.

The high voltage power supply provides an appropriate acceleration voltage to electrodes in focusing column 116 for energizing and focusing ion beam 118. When it strikes substrate 122, material is sputtered, that is physically ejected, from the sample. Alternatively, ion beam 118 can decompose a precursor gas to deposit a material.

High voltage power supply 134 is connected to ion source 114 as well as to appropriate electrodes in ion beam focusing components 116 for forming an approximately 1 keV to 60 keV ion beam 118 and directing the same toward a sample. Deflection controller and amplifier 136, operated in accordance with a prescribed pattern provided by pattern generator 138, is coupled to deflection plates 120 whereby ion beam 118 may be controlled manually or automatically to trace out a corresponding pattern on the upper surface of substrate 122. In some systems the deflection plates are placed before the final lens, as is well known in the art. Beam blanking electrodes (not shown) within ion beam focusing column 116 cause ion beam 118 to impact onto blanking aperture (not shown) instead of substrate 122 when a blanking controller (not shown) applies a blanking voltage to the blanking electrode.

The ion source 114 typically provides an ion beam based on the type of ion source. In some embodiments, the ion source 114 is a liquid metal ion source that can provide a gallium ion beam, for example. In other embodiments, the ion source 114 may be plasma-type ion source that can deliver a number of different ion species, such as oxygen, xenon, and nitrogen, to name a few. The ion source 114 typically is capable of being focused into a sub one-tenth micrometer wide beam at substrate 122 or TEM grid holder 124 for either modifying the substrate 122 by ion milling, ion-induced etching, material deposition, or for the purpose of imaging the substrate 122.

A charged particle detector 140, such as an Everhart-Thornley detector or multi-channel plate, used for detecting secondary ion or electron emission is connected to a video circuit 142 that supplies drive signals to video monitor 144 and receiving deflection signals from a system controller 119. The location of charged particle detector 140 within lower chamber 126 can vary in different embodiments. For example, a charged particle detector 140 can be coaxial with the ion beam and include a hole for allowing the ion beam to pass. In other embodiments, secondary particles can be collected through a final lens and then diverted off axis for collection.

A micromanipulator 147 can precisely move objects within the vacuum chamber. Micromanipulator 147 may comprise precision electric motors 148 positioned outside the vacuum chamber to provide X, Y, Z, and theta control of a portion 149 positioned within the vacuum chamber. The micromanipulator 147 can be fitted with different end effectors for manipulating small objects. In the embodiments described herein, the end effector is a thin probe 150.

A gas delivery system 146 extends into lower chamber 126 for introducing and directing a gaseous vapor toward substrate 122. For example, iodine can be delivered to enhance etching, or a metal organic compound can be delivered to deposit a metal.

System controller 119 controls the operations of the various parts of dual beam system. Through system controller 119, a user can cause ion beam 118 or electron beam 143 to be scanned in a desired manner through commands entered into a conventional user interface (not shown). Alternatively, system controller 119 may control dual beam system in accordance with programmed instructions stored in a memory 121. In some embodiments, dual beam system incorporates image recognition software to automatically identify regions of interest, and then the system can manually or automatically extract samples in accordance with the invention. For example, the system could automatically locate similar features on semiconductor wafers including multiple devices and take samples of those features on different (or the same) devices.

In operation in accordance with the techniques disclosed herein, system 100 images a working surface (e.g., a cutface) of a sample 122, the sample 122 being a chunk previously removed from a substrate. The chunk, which may be about 1 μm in thickness, may be attached to TEM holder 124 in this example. As used herein, the working surface is a side surface of the chunk, the chunk needing to be thinned into a final lamella thickness. The sample 122 may include structures that should be aligned/oriented to the ion beam 118, such as in terms of rotation and/or tilt, so that during the final lamella formation, structures that require subsequent imaging are not removed. The image of the newly exposed surface can be acquired using either the electron column 141 or the FIB 111.

Layers of sample 122 can be removed from the working surface. The removal of a layer may be performed using FIB milling or ion induced etching using a gas precursor. Layers can be removed in smaller “slices” according to certain embodiments, in which slices of about 1 nm to 5 nm are removed sequentially. After the slice is removed, the newly exposed surface is imaged. The process of image acquisition and slice removal may be repeated for 25, 50, 75, or 100 times, but any other number of slices are contemplated herein. The working surface of the lamella can show structures, such as lines of devices including FETs, which are desired to be imaged and/or analyzed.

The removal of a layer of material from the sample 122 can be done by directing the FIB 111 toward a portion of the sample 122 in a pattern. For example, the ion beam may raster over the surface of the sample 122 in the portion, removing the desired layer. The images of the working surface as the material is removed can be used to determine the endpoint of the milling process with the FIB 111.

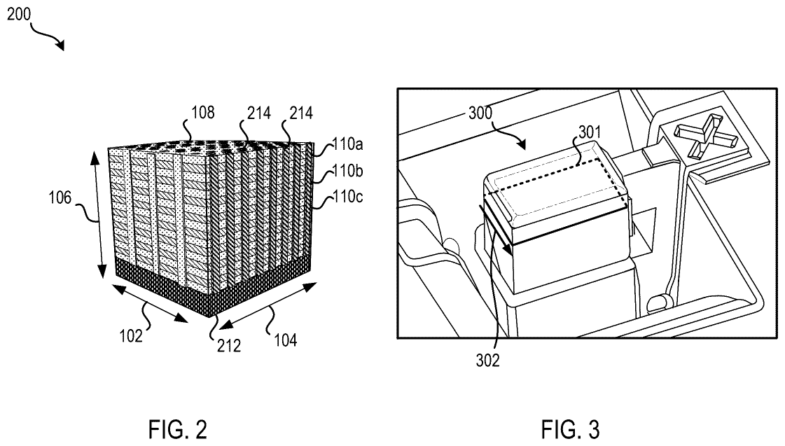

FIG. 2 is a multi-layer structure 200 to illustrate the systems and methods described herein. The multi-layer structure 200 can be a sample including one or more regions of interest and/or one or more features of interest. The multi-layer structure 200 described herein may include layers for a particular application (e.g., transistors), but the embodiments are not limited as such. Furthermore, the multi-layer structure 200 may include features that are dependent on the nature of the sample (e.g., wordline cuts, channels, etc., in the case of VNAND), but other features than those explicitly described herein may be included in the multi-layer structure 200. The multi-layer structure 200 is characterized by a length 102, a width 104, and a depth 106, and the multi-layer structure 200 includes a top surface 108. The multi-layer structure 200 may include a plurality of layers 110. The plurality of layers 110 may include alternating layers wherein the alternative layers having different material composition. For example, alternative layers may include conductive layers interleaved with insulating layers. Throughout this document, the term “wordline” (commonly associated with multi-layers structures that act as memory structures) may be used interchangeably with the term “layer”. The plurality of layers 110 may be formed by various processes including deposition or growth processes known in the semiconductor art.

In some embodiments, the multi-layer structure 200 may include a three-dimensional or vertically stacked NAND memory device (e.g., 3D NAND or V-NAND), and the layer may be a conductive layer or insulating layer of the NAND memory device. The plurality of layers 110 may include any suitable material. In one example, the multi-layer structure 200 may include a plurality of layers 110 formed of an insulating material such as oxide alternating with layers or wordlines formed of a conductive or semiconductive material including nitride, tungsten, etc. The plurality of layers 110 may be grown or deposited sequentially in a vertical direction (along a depth 106) on a substrate 212 toward the top surface 108 of the multi-layer structure 200. In various embodiments, the multi-layer structure 200 includes one or more channels 214.

For various applications, it may be desirable to isolate a specific selected layer 110a at a particular feature depth (along depth 106) within the multi-layer structure 200 for further analysis. Imaging processing may be used to assess outcomes of the manufacturing operation used to produce the multi-layer structure 200. In particular, process information may be obtained when the selected layer 110a is isolated as a planar lamella that enables viewing from an orientation that is parallel to the depth 106 of the multi-layer structure 200. According to various known techniques, isolation of a specific layer from an interim or final structure has been difficult due to the complexities of visualizing and counting layers and correlating this count information with the sample in such a way that the specific layer can be identified, isolated, and analyzed. Various embodiments described herein may discuss isolating a single layer although it should be appreciated by one having ordinary skill in the art upon reading the present disclosure would appreciate that at least some of the embodiments may be applied to isolating a subset of layers where the isolated layers can, but need not, be adjacent to each other.

Various extraction operations known in the art may be used to remove material of the multi-layer structure 200 to form a particular size of the multi-layer structure 200 (e.g., a planar lamella) including charged particle milling or etching operations. Details of chunk preparation and the slice-and-view methodology are described below and also in U.S. Pat. No. 11,264,200 assigned to FEI Company and entitled “Lamella alignment based on a reconstructed volume,” the entire contents of which are hereby incorporated by reference.

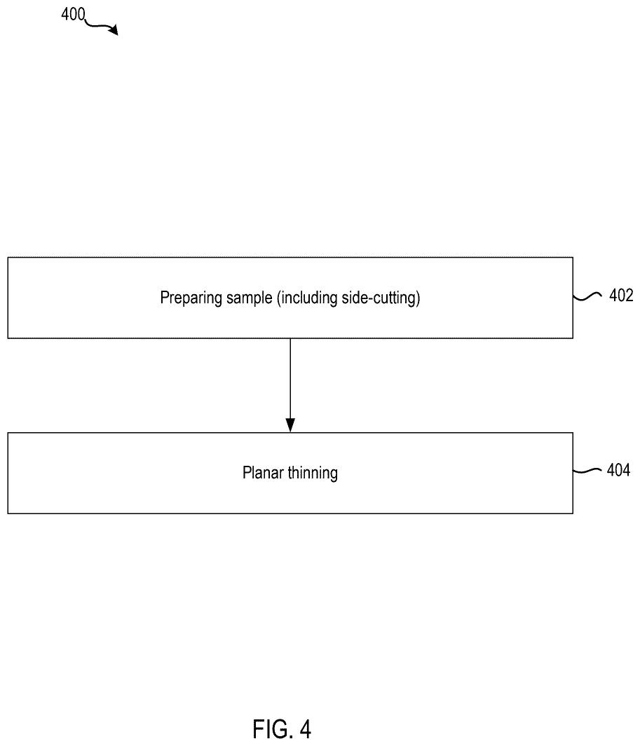

FIG. 3 is a planar lamella formed from a multi-layer structure, according to some embodiments. The planar lamella 300 may be formed from a sample 301 (e.g., a multi-layer structure, such as multi-layer structure 200 described above). The view shown in FIG. 3 depicts a face of the sample 301 after an initial formation technique, for example a cut and lift out technique. The portion of the sample 301 at the right includes a fiducial used to help guide the initial formation of the planar lamella 300. The material of the sample 301 near the fiducial is typically not of interest in the analysis and forms a structural component of the lamella for handling in the dual beam charged particle microscope. For example, the sample 301 may be attached to TEM holder 124 of FIG. 1 via material to the right of the fiducial.

A thinning direction 302 is illustrated relative to the planar lamella 300 as shown in FIG. 3. Because of the scale of the structures (e.g., nanometer scale structures for semiconductor devices), to obtain suitable images of a region of interest of the planar lamella 300, the planar lamella 300 may be thinned to a thickness of less than about 12 nm. Thinning the planar lamella 300 may include removing material from the sample 301 at the face of the planar lamella 300 shown in FIG. 3.

Thinning of the planar lamella 300 can proceed in several steps in which a layer of material is removed at each step. For example, a first layer of material can be removed from the planar lamella 300. Subsequently, a second layer (or third, or suitable number of additional layers) can be removed from an additional portion of the planar lamella 300. The energy of the ion beam can, but need not, be different for the removal of each layer.

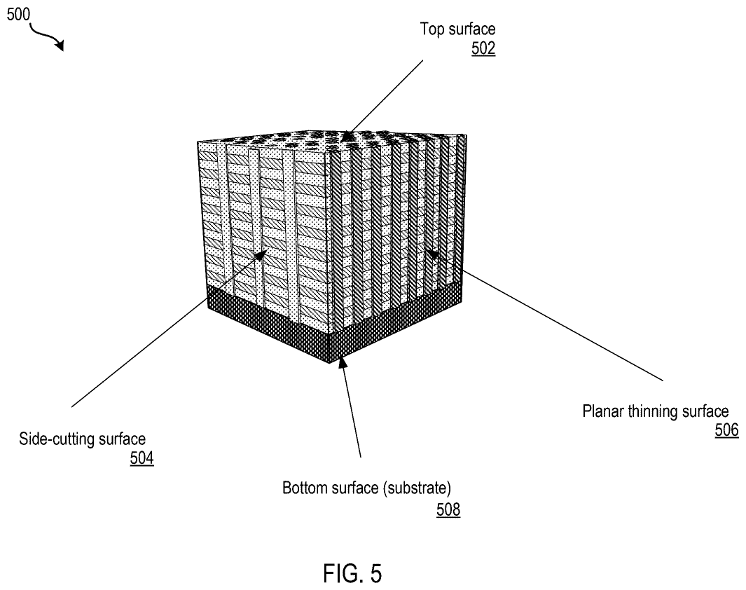

FIG. 4 is a schematic 400 of processing a planar lamella from a multi-layer structure, according to some embodiments. Processing a planar lamella from a multi-layer structure, such as multi-layer structure 200 described in detail above, may include a step 402 including preparing a sample including side-cutting. The multi-layer structure may include multiple regions of interest and/or features (e.g., multiple worldline cuts and channels). However, each region of interest includes only a subset thereof (e.g., one wordline and a particular number of channels). The parameters of the subset (e.g., number of wordlines and/or channels) may be predefined by a user and be implemented as a setting for the system. Side-cutting enables reducing the size of the multi-layer structure according to the parameters before the planar thinning of step 404.

Step 404 includes planar thinning. Here, planar thinning enables the isolation or extraction of a subset of the layers (e.g., a single layer or one or more layers). The number of isolated or extracted layers and/or location (e.g., depth in the multi-layer structure) can also be parameters predefined by a user and/or indicated by a user setting. In various embodiments, thinning of the multi-layer structure to the final planar lamella may be conducted by capturing images of the thinning process from different angles and calculating the thickness of the planar lamella or interim structure using image processing. The thinning process may end when the planar lamella has the correct thickness as determined by processing the images at the off-angle view, to be described in further detail below.

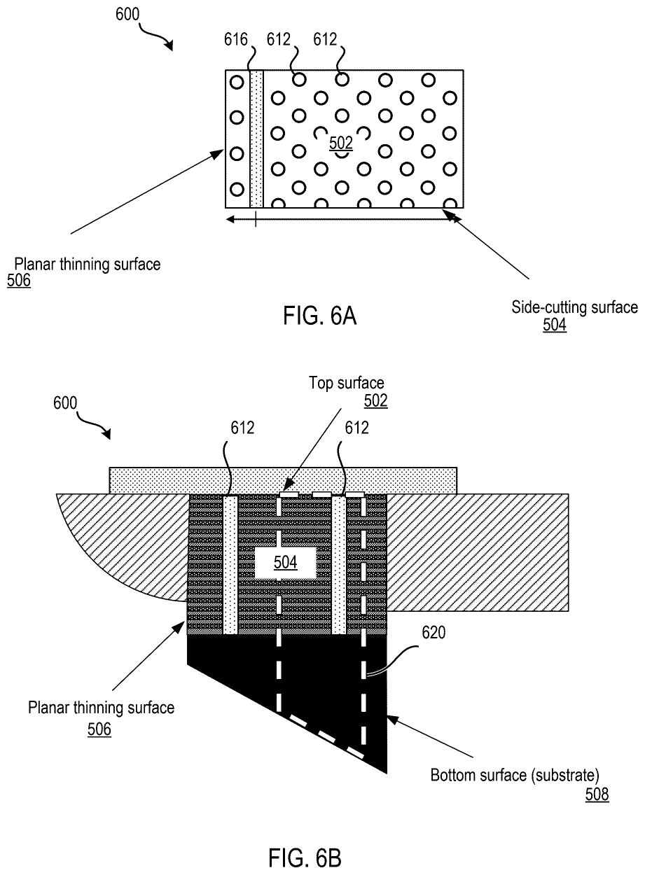

FIG. 5 is a multi-layer structure showing spatial relationships for processing a planar lamella, according to some embodiments. For example, a top surface 502 of a multi-layer structure 500 is shown relative to a side-cutting surface 504 (e.g., orthogonal or intersecting with the top surface 502) and a planar thinning surface 506 (e.g., parallel to the top surface 502). The top surface 502 is visible during TEM analysis. In some embodiments, the multi-layer structure 500 may be positioned within the system such that the side-cutting surface 504 is cut at an angle extending between the top surface 502 and a bottom surface 508. The bottom surface 508 may include a substrate in at least some embodiments. During the side-cutting (e.g., step 402 above), the side-cutting surface 504 can be imaged, while being diagonally cut and/or edges thereof iteratively sliced off. During the planar thinning (e.g., step 404 above), layers above and/or below the planar thinning surface 506 can be removed.

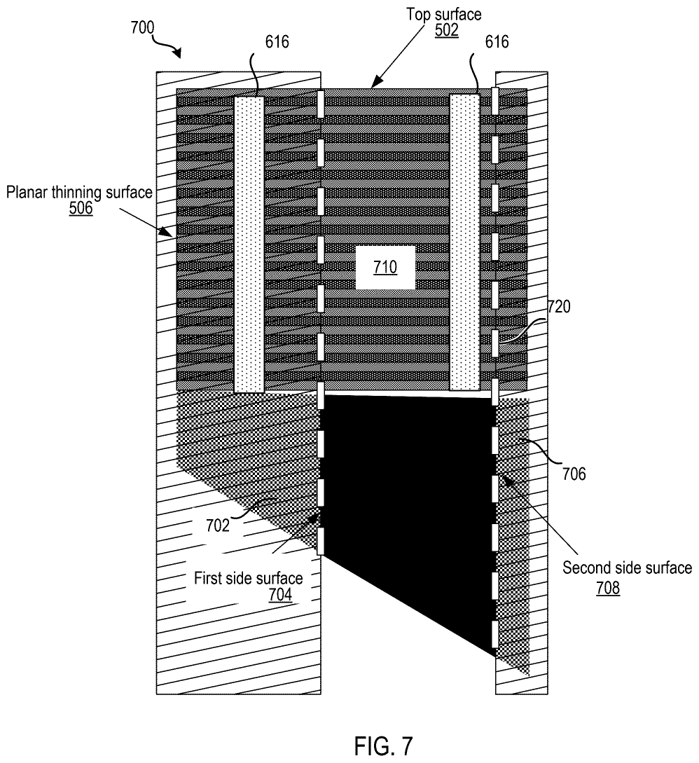

FIG. 6A illustrates a top view of a multi-layer structure, according to some embodiments. FIG. 6A illustrates the top surface 502 of the multi-layer structure 600. Accordingly, similar features may be similarly numbered and have similar form and function unless otherwise noted herein. The multi-layer structure 600 may include one or more channels 612 which may be visible from the top view as shown in FIG. 6A. The one or more channels 612 (e.g., an example of a feature of the multi-layer structure) may be formed in a linearly offset pattern such as that shown in FIG. 6A or the one or more channels 612 may be aligned in other configurations or randomized in view of the intended application and formation of the multi-layer structure 600. Further visible in this view, a wordline cut 616 is formed in the multi-layer structure 500. According to various embodiments described herein, a wordline cut 616 may be an example of a feature within the region of interest.

FIG. 6B illustrates a side view of the multi-layer structure of FIG. 6A, according to some embodiments. In particular, FIG. 6B illustrates the side-cutting surface 504 relative to the planar thinning surface 506 and the top surface 502 prior to a side-cutting process (e.g., such as step 402 of FIG. 4 described above). In contrast, FIG. 6A illustrates a view of the multi-layer structure 500 after the side-cutting. In this case, the parameters (e.g., predefined by a user, a user setting, etc.) indicate that one wordline, and one column of channels to the left, and 9 columns of channels to the right are of interest, resulting in the top view of FIG. 6A.

Visible in this view of FIG. 6B, channels 612 extend from the top surface 502 to a substrate or bottom surface 508. A region of interest (ROI) 620 is depicted by the bounded inner rectangle of FIG. 6B. The region of interest 620 may include a region where one or more structures are present such as wordline cuts or the like.

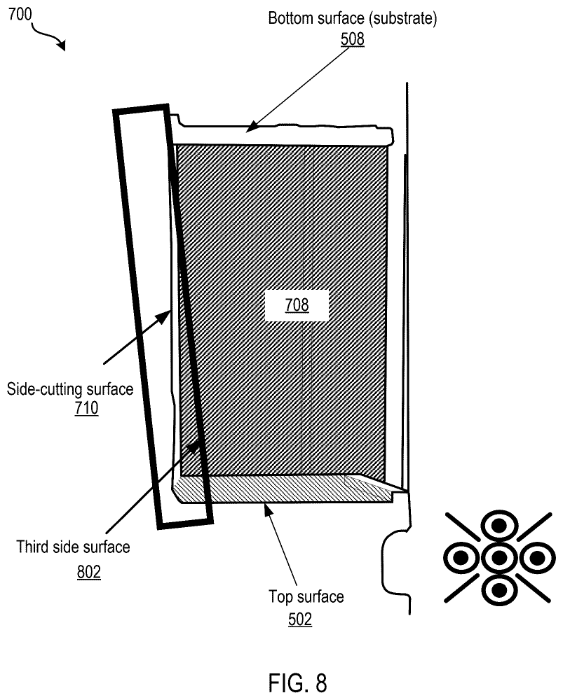

FIG. 7 illustrates processing of a sample to form a multi-layer structure of a particular size, according to some embodiments. For example, FIG. 7 is a side view of the structure shown in FIG. 6B and shows the sides that are removed to result in the final structure, having the top view of FIG. 6A. In various embodiments, the multi-layer structure 700 may be referred to as a sample used to form a multi-layer structure of a particular size or a particular size chunk 720. As shown in FIG. 7, the side-cutting surface 710 of the sample is facing outward from the page. The particular size chunk 720 may be formed at least by removing a first portion 702 of the sample 700. The first portion 702 may be removed to define the first side surface 704 of the particular size chunk 720. The first portion 702 may be removed from the sample 700 in any manner known in the art such as various milling or polishing techniques or the like. In exemplary embodiments, the first portion 702 may be removed, via ion beams as described above, in slices of the first portion 702 where the slices are parallel to the first side surface 704.

In various embodiments, the particular size chunk 720 (e.g., the multilayer structure having a particular size) may be further formed by at least removing a second portion 706 of the sample 700. The second portion 706 may be removed to define the second side surface 708 opposite the first side surface 704. The first portion 702 may be the same size as the second portion 706 or the first portion 702 may be larger or smaller than the second portion 706 depending on the particular size chunk 720. The particular size may be a distance d between the first side surface 704 and the second side surface 708. As shown in FIG. 7, the side-cutting surface 710 intersects the first side surface 704 and the second side surface 708.

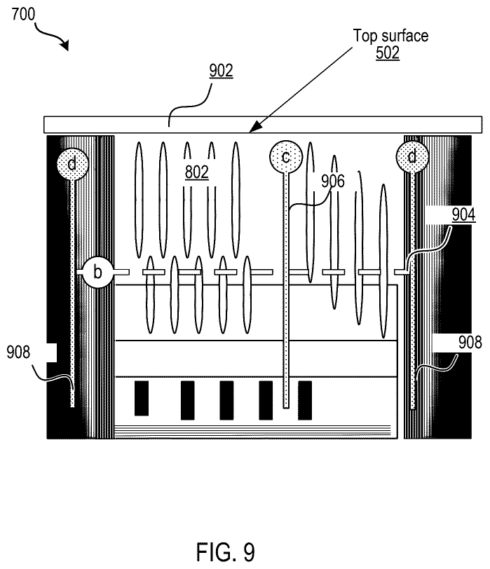

FIG. 8 illustrates a sidecut of a multi-layer structure to form a sample, according to some embodiments. The first portion 702 and the second portion 706 may be removed by at least cutting (e.g., polishing) a third side surface 802 into the side-cutting surface 710. In various embodiments, the third side surface 802 is cut at a non-zero angle relative to the top surface 502 as shown in FIG. 8. An image may be taken of the third side surface 802 and the first portion 702 and the second portion 706 may be removed (e.g., in slices) based at least in part on the image. In some embodiments, the sample 700 may be rotated and/or tilted after the third side surface 802 is polished to obtain the image of the third side surface 802. The third side surface 802 may intersect the first side surface 704 and the second side surface 708 such that the first side surface 704 and the second side surface 708 are visible in the image, to be described in further detail below.

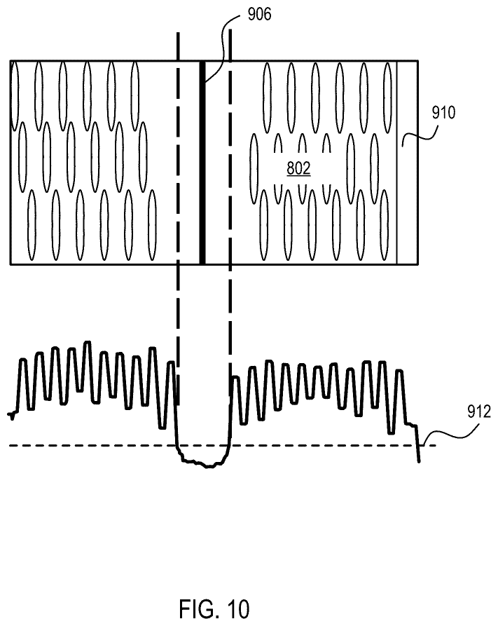

FIG. 9 illustrates processing of a multi-layer structure to form a sample, according to some embodiments. After polishing the third side surface 802 as in FIG. 8, the sample 700 may be rotated and/or tilted such that the third side surface 802 is visible (e.g., facing outward form the page as shown in FIG. 9). In this view, various steps a, b, c, d, etc., are shown. Although the steps are described in one configuration herein, it should be understood that any of the steps may be omitted or performed in a different order or additional steps may be performed according to various embodiments. In at least some embodiments, as shown by a, a protective layer 902 may be applied to a top surface 502 of the sample 700. The protective layer 902 may include tungsten (W), carbon (C), silicon dioxide (SiO₂) and be in a thickness between 50 nm and 2000 nm.

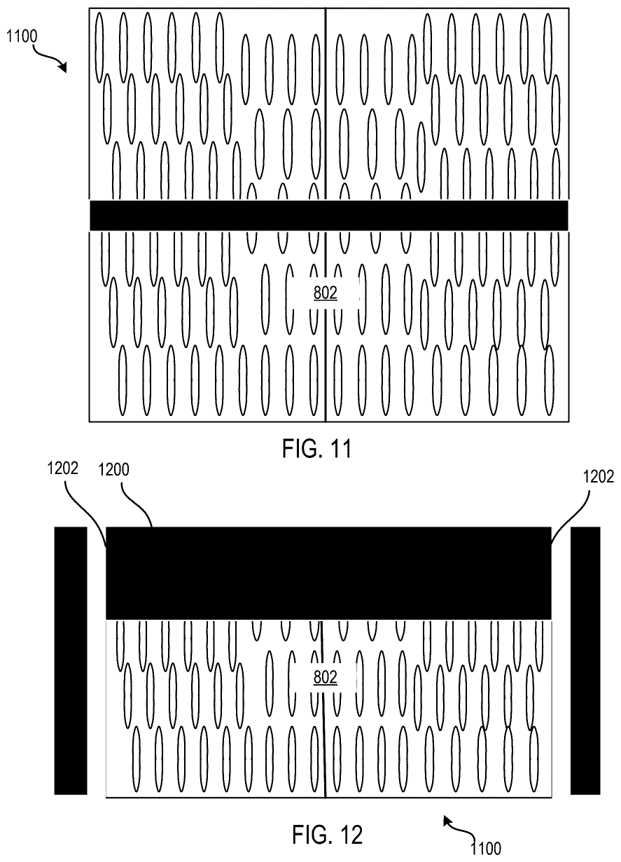

As shown in b, a target position 904 within the third side surface 802 may be determined. According to some embodiments, the image of the third side surface 802 of the sample 700 may be used to determine the target position 904. A target position 904 may be selected and determined according to techniques known in the art. In some embodiments, determining the target position 904 includes, based on the image, detecting a set of features of the sample 700 in the third side surface 802. According to various embodiments, the set of features may include wordlines, wordline cuts, channels, circuits, bitlines, wordline contacts, or the like. As shown in c, the target position 904 may be a wordline cut 906 with channels on either side. A center of the wordline cut 906 may be calculated based on techniques known in the art. FIG. 10 illustrates a method of detecting a feature, such as the wordline cut 906. For example, a standard deviation of the space between the channels 910 may be calculated. A feature may be determined to be present for any value outside of a predefined threshold 912.

Further details with respect to obtaining any of the images as described herein are described in U.S. application Ser. No. 18/592,053 assigned to FEI Company and entitled “nSystems and Methods for Accurate Layer Detection and Analysis in Charged Particle Microscopes,” the entire contents of which are hereby incorporated by reference.

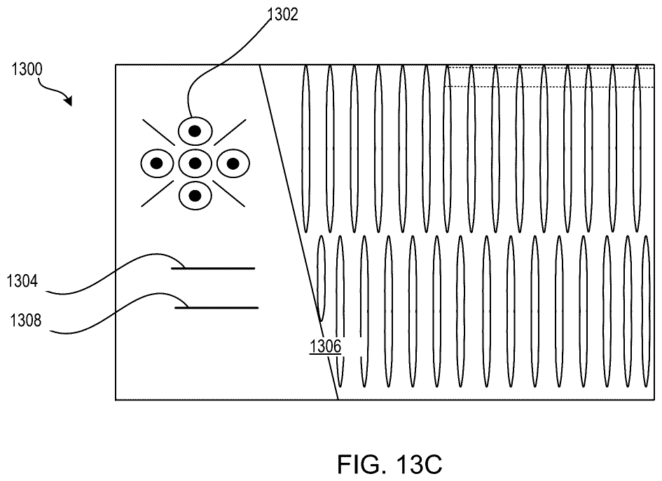

The image may be further used to determine edges 908 of any surface. For example, as shown in d, the edges 908 of the second side surface 708 may be readily visible in the image. The accuracy of the detection of the edges 908 as illustrated in FIG. 9 may be improved by applying a deposition layer proximate to the regions of interest of the multi-layer structure 700. The deposition layer for enabling this high contrast is discussed in further detail below with respect to FIG. 12. The first portion 702 and the second portion 706 may be cut based on the set of features (e.g., in this exemplary sample 700, the wordline cut 906), the edges 908 of the third side surface 802, and at least one parameter of the particular size chunk 720 (e.g., a region of interest). A parameter may include a width, height, depth, number of channels, number of features, etc.

In at least some embodiments, a material may be deposited proximate to the particular size chunk 720 for increasing the visibility of the edges of the third side surface 802 (e.g., to improve the image processing, resulting in improving the edge detection and the side-cutting), to be described in further detail below. The material may include C, SiO₂, W, platinum (Pt), or the like, and may be deposited to a thickness between 10 nm and 100 nm. The thickness of the material may be deposited such that the material is not transparent. The first portion 702 and the second portion 706 may be cut based at least in part on image edge detection of the particular size chunk 720 having a material deposited proximate to a top surface (e.g., top surface 502) thereof.

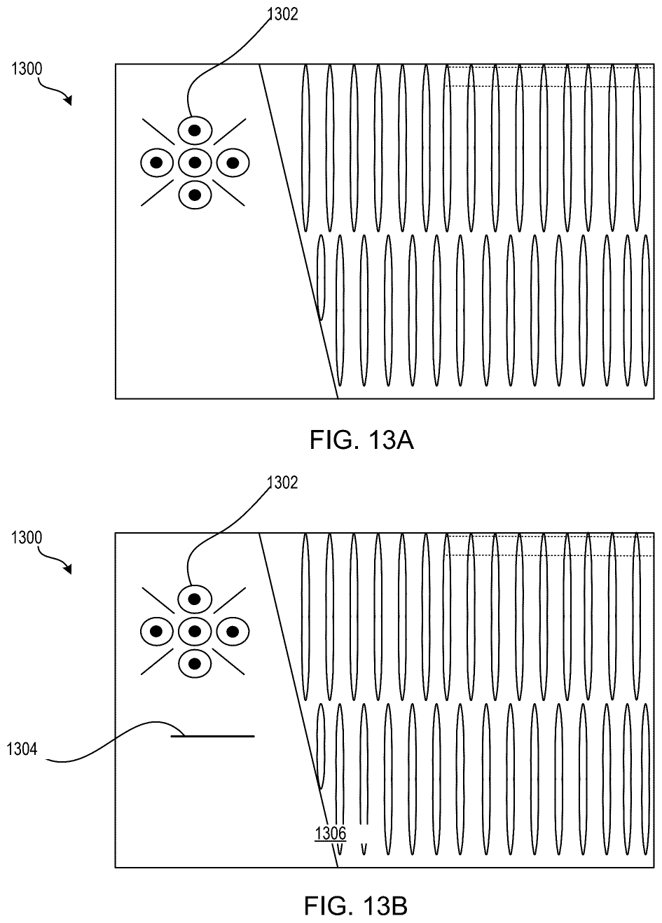

FIG. 11 illustrates a region of interest of a multi-layer structure. According to various embodiments, a region of interest 1100 may be determined relative to the target position 904. For example, a first position of the protective layer 902 on the top surface 502 (such as shown in FIG. 8), a position of a target in the third side surface 802 (such as wordline cut 906), a set of features of the third side surface, and the edges 908 of the third side surface 802 may be used to define the region of interest 1100. The region of interest 1100 may include the target position 904 and be positioned at the second position away from the first position. Further, the region of interest 1100 may include at least a portion of the set of features and have edges.

FIG. 12 illustrates deposition of a material proximate to a region of interest of a multi-layer structure, according to some embodiments. After determining a region of interest 1100, a material 1200 may be deposited on or near the region of interest 1100 for improving the image quality of the third side surface 802. The material 1200 may be used as a new physical mark for recognition. Furthermore, the material 1200 provides a homogenous contrast in the image processing. For example, the edges 1202 of the region of interest 1100 are distinct and have higher contrast that the channels or other features in the region of interest 1100. The material may include C, SiO₂, W, platinum (Pt), or the like, and may be deposited to a thickness between 10 nm and 100 nm. Referring to embodiments described above and especially with respect to FIG. 7, a first portion 702 and a second portion 706 may be cut away from the sample 700 based on analysis of images showing the third side surface 802 and image edge detection of the region of interest 1100 as illustrated at least in FIGS. 9-11.

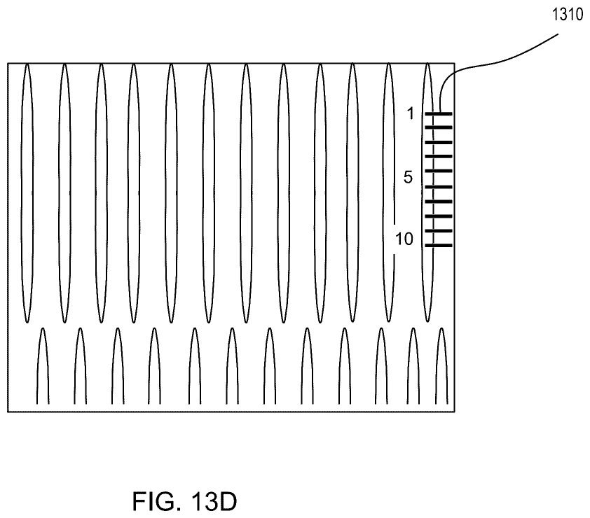

FIGS. 13A-13D illustrate a process for preparing a planar lamella from a multi-layer structure, according to some embodiments. In an example, this process can be performed after the side-cutting described herein above. However, it is possible to apply this process without or independent of the side-cutting, or even be followed by side-cutting. According to various embodiments, the multi-layer structure 1300 may include a fiducial 1302 used to help guide the formation of the planar lamella. The multi-layer structure 1300 may include multiple layers that are parallel to a top surface of the multi-layer structure 1300. FIG. 13B illustrates a first marker 1304 milled in a first side surface 1306 of the multi-layer structure 1300. A first image may be obtained of the first side surface 1306 where the first image includes the first marker 1304. The first marker 1304 may be milled based on a determination of a fiducial 1302 on the first side surface 1306. Although the milled markers shown in FIGS. 13A-13D are shown as lines, one having ordinary skill in the art upon reading the present disclosure would appreciate that the milled markers may include any other shape, line, text, etc.

A pattern offset may be determined based on the first image. For example, a first position of the first marker 1304 may be determined from the first image. According to some embodiments, a second marker 1308 may be milled in the first side surface 1306. FIG. 13C illustrates the second marker 1308 milled in the first side surface 1306. In some embodiments, the second marker 1308 may be milled based on the first marker 1304. A second image may be obtained including the second marker 1308 (and the first marker 1304) visible in the first side surface 1306. The second marker 1308 may be milled at an expected position relative to the first position. The second image including the first marker 1304 and the second marker 1308 may be used to determine a second position of the second marker 1308. For example, the pattern offset may be determined based on a difference between the expected position and the second position. In some embodiments, the pattern offset may be the distance between the two lines (e.g., the first marker 1304 and the second marker 1308) and compared to the position where the second marker 1308 was targeted versus the position where the actual second marker 1308 was milled.

In various embodiments, a target marker 1310 on a target layer of the multiple layers of the is milled into the multi-layer structure 1300 such as shown in FIG. 13D. This target marker may be milled based on the pattern offset. For example, the layer is at a target position. Accordingly, the target marker is to be milled at the target position. The target position is adjusted by the pattern offset such that the milling accurately occurs at the target layer. To illustrate, assume that the target layer is at distance d1 from the top surface. Assume that the pattern offset is a distance d2. Accordingly, rather than setting the milling to occur at distance d3=d1, it is set to occur at distance d3=d1+d2 to account for the pattern offset. The multi-layer structure 1300 may be thinned based on the first marker 1304 such that the target layer is included in the planar lamella and one or more layers of the multiple layers of the multiple layers are excluded from the planar lamella.

According to various embodiments, the first side surface 1306 includes a first portion and a second portion, as described above with respect to other figures. The first image may show that the first portion includes the first marker 1304 and the second portion includes the multiple layers. The target marker may be milled in the second portion.

According to various embodiments, the process of FIGS. 13A-13D include taking two localized images, one at the fiducial and the other at the third surface including the target. In the first image, the fiducial (or any other feature) may be identified and on the other image, the rest of the steps are done as described herein.

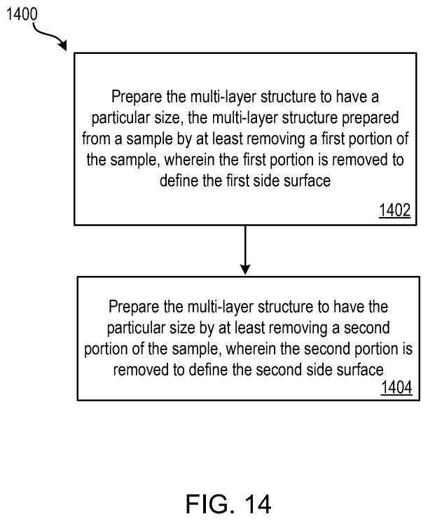

FIG. 14 is a flowchart of a method for preparing a planar lamella from a multi-layer structure as described at least with respect to FIGS. 6A-12. Method 1400 includes various steps. Step 1402 includes preparing the multi-layer structure to have a particular size. Step 1402 may include removing a first portion of the sample and the first portion is removed to define the first side surface as shown at least in FIG. 7. Step 1404 includes preparing the multi-layer structure to have the particular size by at least removing a second portion of the sample. The second portion is removed to define the second side surface as further shown at least in FIG. 7. Additional processing may be performed as described in FIGS. 9-12 to further image the region of interest.

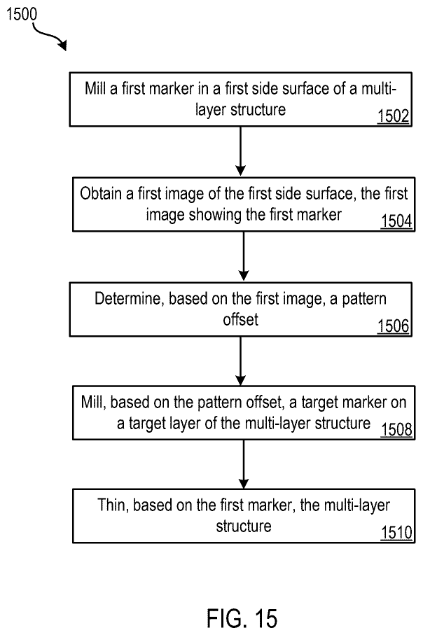

FIG. 15 is a flowchart of a method for preparing a planar lamella from a multi-layer structure. Method 1500 includes various steps. In various embodiments, the flowchart of FIG. 15 may follow the lamella preparation per the flow of FIG. 14 above. Step 1502 includes milling a first marker in a first side surface of the multi-layer structure. The multi-layer structure may include multiple layers that are parallel to a top surface of the multi-layer structure as described in detail above.

Step 1504 includes obtaining a first image of the first side surface, the first image showing the first marker. The first image may be obtained using applicable techniques which would be appreciated by one having ordinary skill in the art upon reading the present disclosure.

Step 1506 includes determining, based on the first image, a pattern offset. As described above, a pattern offset may be determined by using a first position of the first marker determined from the first image. Optionally, a second marker may be milled in the first side surface based on the first marker and a second image may be obtained including the second marker (and the first marker) visible in the first side surface. In particular, the second marker may be milled at an expected position relative to the first position. The second image including the first marker and the second marker may be used to determine a second position of the second marker and the pattern offset may be determined based on a difference between the expected position and the second position.

Step 1508 includes milling, based on the pattern offset, a target marker on a target layer of the multiple layers. A target layer may be determined based on various techniques known in the art. For example, a target layer may include one feature or a set of features of interest.

Step 1510 includes thinning, based on the first marker, the multi-layer structure such that the target layer is included in the planar lamella and one or more other layers of the multiple layers are excluded from the planar lamella. Milling may be performed in one or more steps with possibly various ion beam energies (e.g., 30 kV, 2 kV). For example, portions of the multi-structure layer may be removed in slices until the desired thickness or other parameter is met as would be appreciated by one having ordinary skill in the art upon reading the present disclosure.

The systems, apparatus, and methods described herein should not be construed as limiting in any way. Instead, the present disclosure is directed toward all novel and non-obvious features and aspects of the various disclosed embodiments, alone and in various combinations and sub-combinations with one another. The disclosed systems, methods, and apparatus are not limited to any specific aspect or feature or combinations thereof, nor do the disclosed systems, methods, and apparatus require that any one or more specific advantages be present, or problems be solved. Any theories of operation are to facilitate explanation, but the disclosed systems, methods, and apparatus are not limited to such theories of operation.

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed systems, methods, and apparatus can be used in conjunction with other systems, methods, and apparatus. Additionally, the description sometimes uses terms like “produce” and “provide” to describe the disclosed methods. These terms are high-level abstractions of the actual operations that are performed. The actual operations that correspond to these terms will vary depending on the particular implementation and are readily discernible by one of ordinary skill in the art.

In some examples, values, procedures, or apparatuses are referred to as “lowest”, “best”, “minimum,” or the like. It will be appreciated that such descriptions are intended to indicate that a selection among many used functional alternatives can be made, and such selections need not be better, smaller, or otherwise preferable to other selections.

What is claimed is:

1. A method for preparing a planar lamella from a multi-layer structure, the method comprising:
milling a first marker in a first side surface of the multi-layer structure, the multi-layer structure including multiple layers that are parallel to a top surface of the multi-layer structure;
obtaining a first image of the first side surface, the first image showing the first marker;
determining, based on the first image, a pattern offset; and
milling, based on the pattern offset, a target marker on a target layer of the multiple layers.

2. The method of claim 1, further comprising:
thinning, based on the first marker, the multi-layer structure such that the target layer is included in the planar lamella and one or more other layers of the multiple layers are excluded from the planar lamella.

3. The method of claim 1, further comprising:
milling, based on the first image, a second marker in the first side surface; and
obtaining a second image of the first side surface, the second image showing the first marker and the second marker, wherein the pattern offset is further determined based on the second image.

4. The method of claim 1, further comprising:
determining, based on the first image, a first position of the first marker;
milling, based on the first position, a second marker in the first side surface such that the second marker is milled at an expected position relative to the first position; and
obtaining a second image of the first side surface, the second image showing the second marker; and
determining, based on the second image, a second position of the second marker, wherein the pattern offset is determined based on a difference between the expected position and the second position.

5. The method of claim 4, wherein the first marker is a first line milled based on a determination of a fiducial on the first side surface, and wherein the second marker is a second line milled based on the first marker.

6. The method of claim 1, wherein the first side surface includes a first portion and a second portion, wherein the first image shows that the first portion includes the first marker and that the second portion includes the multiple layers.

7. The method of claim 6, wherein the target marker is milled in the second portion.

8. The method of claim 1, further comprising:
preparing the multi-layer structure to have a particular size, the multi-layer structure prepared from a sample by at least removing a first portion of the sample, wherein the first portion is removed to define the first side surface.

9. The method of claim 8, wherein the multi-layer structure is further prepared from the sample by at least removing a second portion of the sample, wherein the second portion is removed to define a second side surface opposite the first side surface, and wherein the particular size is a distance between the first side surface and the second side surface.

10. The method of claim 9, wherein the first portion and the second portion are removed by at least:
polishing a third side surface of the sample, wherein the third side surface intersects the first side surface and the second side surface and is polished at a non-zero angle relative to the top surface;
obtaining a second image of the third side surface; and
cutting the first portion and the second portion based on the second image.

11. The method of claim 9, wherein the first portion and the second portion are removed by at least:
obtaining a second image of a third side surface of the sample, wherein the third side surface intersects the first side surface and the second side surface;
determining, based on the second image, a set of features of the sample in the third side surface, wherein the second image shows the set of features;
determining, based on the second image, edges of the third side surface;
determining a parameter indicating the particular size; and
cutting the first portion and the second portion based on the set of features, the edges, and the parameter.

12. The method of claim 9, wherein the first portion and the second portion are removed by at least:
obtaining a second image of a third side surface of the sample, wherein the third side surface intersects the first side surface and the second side surface;
determining a region of interest within the third side surface;
depositing a material in the region of interest; and
cutting the first portion and the second portion based on analysis of images showing the third side surface and based on image edge detection of the region of interest.

13. The method of claim 12, wherein the region of interest is determined by at least:
based on the second image, determining:
a first position of a protective layer on the top surface;
a second position of a target in the third side surface;
a set of features of the third side surface; and
edges of the third side surface; and
defining the region of interest to include the target, be positioned at the second position away from the first position, include a portion of the set of features, and have the edges.

14. The method of claim 9, wherein the first portion is removed by at least:
obtaining images of a third side surface of the sample, wherein the third side surface intersects the first side surface and the second side surface; and
removing, via ion beams and the images, slices of the first portion, wherein the slices are parallel to the first side surface.

15. One or more non-transitory computer-readable storage media storing instructions that, upon execution on a system, cause the system to perform operations comprising:
milling a first marker in a first side surface of the multi-layer structure, the multi-layer structure including multiple layers that are parallel to a top surface of the multi-layer structure;
obtaining a first image of the first side surface, the first image showing the first marker;
determining, based on the first image, a pattern offset;
milling, based on the pattern offset, a target marker on a target layer of the multiple layers; and
thinning, based on the first marker, the multi-layer structure such that the target layer is included in the planar lamella and one or more other layers of the multiple layers are excluded from the planar lamella.

16. The one or more non-transitory computer-readable storage media of claim 15, wherein the operations further comprise:
milling, based on the first image, a second marker in the first side surface; and
obtaining a second image of the first side surface, the second image showing the first marker and the second marker, wherein the pattern offset is further determined based on the second image.

17. The one or more non-transitory computer-readable storage media of claim 15, wherein the operations further comprise:
determining, based on the first image, a first position of the first marker;
milling, based on the first position, a second marker in the first side surface such that the second marker is milled at an expected position relative to the first position; and
obtaining a second image of the first side surface, the second image showing the second marker; and
determining, based on the second image, a second position of the second marker, wherein the pattern offset is determined based on a difference between the expected position and the second position.

18. The one or more non-transitory computer-readable storage media of claim 15, wherein the operations further comprise:
preparing the multi-layer structure to have a particular size, the multi-layer structure prepared from a sample by at least removing a first portion of the sample, wherein the first portion is removed to define the first side surface.

19. The one or more non-transitory computer-readable storage media of claim 18, wherein the multi-layer structure is further prepared from the sample by at least removing a second portion of the sample, wherein the second portion is removed to define a second side surface opposite the first side surface, and wherein the particular size is a distance between the first side surface and the second side surface.

20. The one or more non-transitory computer-readable storage media of claim 19, wherein the first portion and the second portion are removed by at least:
obtaining a second image of a third side surface of the sample, wherein the third side surface intersects the first side surface and the second side surface;
determining a region of interest within the third side surface;
depositing a material in the region of interest; and
cutting the first portion and the second portion based on analysis of images showing the third side surface and based on image edge detection of the region of interest.
